(19) United States
(12) Patent Application Publication
(10) Pub. No.: US 2026/0156813 A1
(43) Pub. Date: Jun. 4, 2026

(54) SEMICONDUCTOR DEVICE HAVING DEVICE ISOLATION PATTERN AND INTEGRATED CIRCUIT DEVICE INCLUDING SAME

(71) Applicant: Samsung Electronics Co., Ltd., Suwon-si (KR)

(72) Inventors: Kyuseok Lee, Suwon-si (KR); JOONYOUNG KOH, Suwon-si (KR); HYUNJU SUNG, Suwon-si (KR); HANBYUL YU, Suwon-si (KR); Jiyun Lee, Suwon-si (KR)

(21) Appl. No.: 19/363,891

(22) Filed: Oct. 21, 2025

(30) Foreign Application Priority Data
Dec. 3, 2024 (KR) 10-2024-0177681

(51) Int. Cl. H10B 12/00; G11C 11/4091

(52) U.S. Cl. CPC H10B 12/50; G11C 11/4091; H10B 12/315

(57) ABSTRACT

A semiconductor device includes a substrate having a first trench and a second trench, a device isolation pattern provided in the first trench to define an active region in the substrate, a gate insulating pattern provided on the active region, a gate electrode provided on the gate insulating pattern, and a dimple pattern filling at least a portion of the second trench and having a concave upper surface. At least a portion of the dimple pattern may overlap the gate electrode in a plan view, and a depth of the second trench may be in a range from 80% to 100% of a depth of the first trench.

### CROSS-REFERENCE TO RELATED APPLICATION(S)

This U.S. non-provisional application claims priority under 35 USC § 119 to Korean Patent Application No. 10-2024-0177681, filed on Dec. 3, 2024, in the Korean Intellectual Property Office, the disclosure of which is herein incorporated by reference in its entirety.

### BACKGROUND

Example embodiments relate to a semiconductor device and an integrated circuit device including the same.

With the increasing demand for miniaturization, multifunctionality, and high performance in electronic products, high-capacity integrated circuit devices are often required. Increased integration density is generally required to provide high-capacity integrated circuits. As the size of memory devices such as a DRAM decreases, a gate length of transistors configured to drive the memory devices (for example, transistors constituting a sense amplifier) may also decrease and/or variations in threshold voltage may occur/increase.

### SUMMARY

Example embodiments provide a semiconductor device and/or an integrated circuit device with a reduced feature size while exhibiting improved electrical characteristics.

According to an example embodiment, a semiconductor device includes a substrate having a first trench and a second trench, a device isolation pattern provided in the first trench to define an active region in the substrate, a gate insulating pattern provided on the active region, a gate electrode provided on the gate insulating pattern, and a dimple pattern filling at least a portion of the second trench and having a concave upper surface. At least a portion of the dimple pattern may overlap the gate electrode in a plan view, and a depth of the second trench may be in a range from 80% to 100% of a depth of the first trench.

According to an example embodiment, a semiconductor device includes a substrate having an active region defined by a device isolation pattern, a dimple pattern defined by the active region, a gate electrode provided on the active region, and comprising a portion vertically overlapping the dimple pattern and a portion vertically overlapping the device isolation pattern, and a gate insulating pattern between the gate electrode and the active region. An upper surface of the dimple pattern may be disposed farther from an upper surface of the substrate in a vertical direction than an upper surface of the device isolation pattern is to the upper surface of the substrate in the vertical direction in a portion vertically overlapping the gate electrode.

According to an example embodiment, an integrated circuit device includes a sense amplifier configured to detect a voltage of a bitline and comprising a first PMOS transistor, a second PMOS transistor, a first NMOS transistor, and a second NMOS transistor. At least one of the first PMOS transistor, the second PMOS transistor, the first NMOS transistor, and the second NMOS transistor may include a substrate having a first trench and a second trench, a device isolation pattern provided in the first trench to define an active region in the substrate, a gate insulating pattern provided on the active region, a gate electrode provided on the gate insulating pattern, and at least one dimple pattern filling at least a portion of the second trench and having a concave upper surface. At least a portion of the dimple pattern may overlap the gate electrode in a plan view, and a depth of the second trench may be in a range from 80% to 100% of a depth of the first trench.

According to an example embodiment, a method of manufacturing a semiconductor device includes forming a first trench and a second trench on a substrate, forming a first insulating layer to fill the first and second trenches, performing a planarization process such that the first insulating layer is removed down to an upper surface of the substrate to form a device isolation pattern and a dimple pattern, forming a gate insulating layer and a conductive layer on the substrate, and patterning the gate insulating layer and the conductive layer to form a gate insulating pattern and a gate electrode. The dimple pattern may have a concave upper surface, and the gate electrode may have a protrusion corresponding to and/or protruding toward the concave upper surface of the dimple pattern.

According to an example embodiment, a width of the first trench may be greater than a width of the second trench.

According to an example embodiment, the device isolation pattern may be formed in the first trench, and the dimple pattern may be formed in the second trench.

According to an example embodiment, an upper surface of the dimple pattern may be formed at a lower level than an upper surface of the device isolation pattern.

According to an example embodiment, the upper surface of the device isolation pattern may be formed at the same or substantially the same level as the upper surface of the substrate.

According to an example embodiment, the second trench may include a bottom surface, a first side surface connected to the bottom surface, and a second side surface connected to the upper surface of the substrate and having an inclination angle different from an inclination angle of the first side surface. An edge of the upper surface of the dimple pattern may be in contact with the second side surface.

According to an example embodiment, a depth of the second trench may be 80% to 100% of a depth of the first trench.

According to an example embodiment, the first and second trenches may be formed using the same patterning process.

According to an example embodiment, the planarization process may be performed using an etch-back process and/or a chemical mechanical polishing (CMP) process.

According to an example embodiment, the forming of the device isolation pattern and the forming of the dimple pattern may be performed in the same operation.

### BRIEF DESCRIPTION OF DRAWINGS

FIG. 1 is a plan view of a semiconductor device according to an example embodiment.

FIG. 2A is a cross-sectional view of a semiconductor device according to an example embodiment, taken along line A1-A1′ of FIG. 1.

FIG. 2B is a cross-sectional view of a semiconductor device according to an example embodiment, taken along line B1-B1′ of FIG. 1.

FIG. 3 is an enlarged view of portion X1 of FIG. 2B.

FIGS. 4A to 4E are diagrams, sequentially illustrating a method of manufacturing a semiconductor device according to an example embodiment, and correspond to the cross-sectional view of FIG. 2B.

FIG. 5 is a block diagram of an integrated circuit device according to an example embodiment.

FIG. 6 is a layout diagram of a semiconductor device according to an example embodiment.

FIG. 7 is an equivalent circuit diagram of a sense amplifier according to an example embodiment.

FIG. 8 is a plan view of an integrated circuit device including a semiconductor device according to an example embodiment.

FIGS. 9A to 9C are cross-sectional views of an integrated circuit device according to an example embodiment, taken along lines A2-A2′, B2-B2′, and C-C′ of FIG. 8, respectively.

### DETAILED DESCRIPTION

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

As used herein, components described as being “electrically connected” are configured such that an electrical signal can be transferred from one component to the other (although such electrical signal may be attenuated in strength as it is transferred and may be selectively transferred).

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Hereinafter, example embodiments will be described with reference to the accompanying drawings.

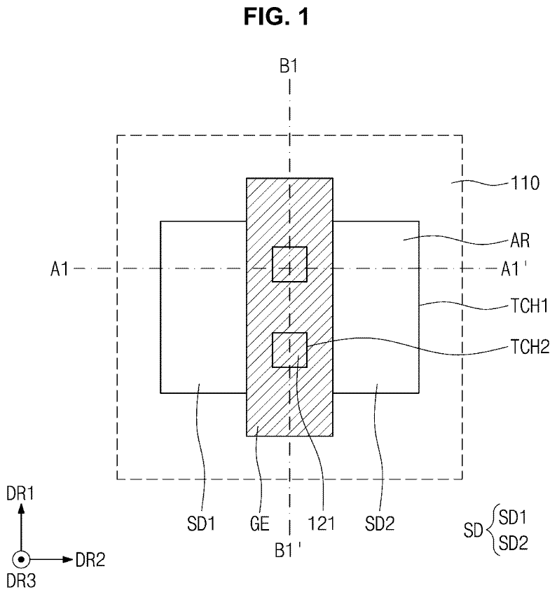

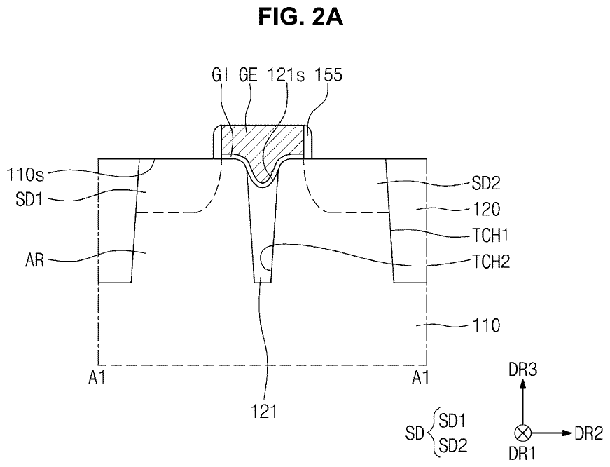

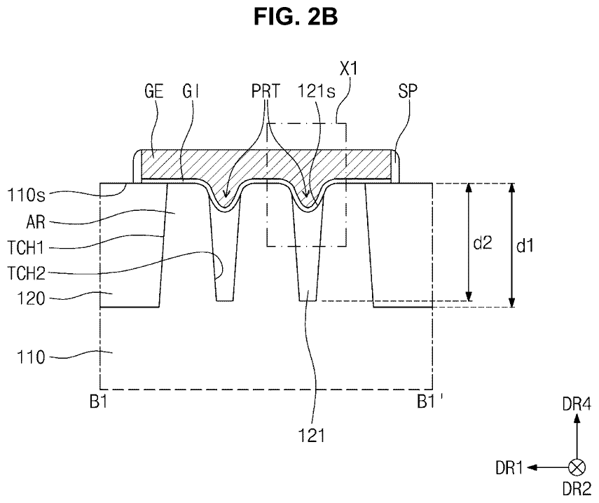

FIG. 1 is a plan view of a semiconductor device according to an example embodiment. FIG. 2A is a cross-sectional view of a semiconductor device according to an example embodiment, taken along line A1-A1′ of FIG. 1. FIG. 2B is a cross-sectional view of a semiconductor device according to an example embodiment, taken along line B1-B1′ of FIG. 1.

Referring to FIGS. 1, 2A, and 2B, a semiconductor device may include a substrate 110 and a gate electrode GE. The substrate 110 may include an active region AR, a device isolation pattern 120, a dimple pattern 121, and first and second source/drain regions SD1 and SD2. For example, the dimple pattern 121 may be a pattern having a dimple on a top/upper surface 121s. For example, the dimple pattern 121 may have a recessed portion in a top/upper surface 121s. For example, the dimple on the top/upper surface 121s of the dimple pattern 121 may be a recess formed in the center or another part of the top/upper surface 121s of the dimple pattern 121. The recessed portion of the top/upper surface 121s may be at a lower level than the other portion of the top/upper surface 121s of the dimple pattern 121.

For descriptive clarity, a direction parallel to an upper surface 110s of the substrate 110 will be referred to as a first direction DR1, a direction parallel to the upper surface 110s of the substrate 110 and perpendicular to the first direction DR1 will be referred to as a second direction DR2, and a direction perpendicular to the upper surface 110s of the substrate 110 will be referred to as a third direction DR3. For example, the first and second directions DR1 and DR2 may be horizontal directions, and the third direction DR3 may be a vertical direction.

The substrate 110 may include, for example, a group IV semiconductor, a group III-V compound semiconductor, or a group II-VI compound semiconductor. For example, the group IV semiconductor may include silicon, germanium, or silicon-germanium. The substrate 110 may be a silicon substrate, a silicon-on-insulator (SOI) substrate, a germanium substrate, a germanium-on-insulator (GOI) substrate, a silicon-germanium substrate, or a substrate including an epitaxial layer. The device isolation pattern 120 may be disposed within the substrate 110 to define the active region AR.

The active region AR may be a region within the substrate 110 into which impurities are implanted. For example, when the semiconductor device is an NMOS transistor, the active region AR may be formed by ion implantation of P-type impurities. When the semiconductor device is a PMOS transistor, the active region AR may be formed by ion implantation of N-type impurities. A plurality of active regions AR may be provided in the substrate 110, and the active regions AR may be portions of the substrate 110 surrounded by the device isolation pattern 120.

The device isolation pattern 120 may surround at least a portion of the active regions AR, spacing the portion apart from other active regions AR. The device isolation pattern 120 may be provided within a first trench TCH1 recessed from an upper surface 110s of the substrate 110. The device isolation pattern 120 may include a silicon oxide, a silicon nitride, a silicon oxynitride, or a combination thereof, and may include a single layer or a plurality of layers.

A portion of the device isolation pattern 120 may be disposed below a gate electrode. For example, a portion of the device isolation pattern may vertically overlap the gate electrode. In the overlap region of the device isolation pattern and the gate electrode, an upper surface of the device isolation pattern 120 may be coplanar or substantially coplanar with the upper surface 110s of the substrate 110. However, the inventive concept is not limited thereto, and the upper surface of the device isolation pattern 120 may not be a flat surface.

The dimple pattern 121 may be disposed within the substrate 110 and disposed below the gate electrode GE. For example, the dimple pattern 121 may be defined by the active region AR, and a side surface and a bottom surface of the dimple pattern 121 may be surrounded by the active region AR.

The dimple pattern 121 may vertically overlap the gate electrode GE. For example, in a cross-sectional view, an entirety of the dimple pattern 121 may overlap the gate electrode GE in the third direction DR3. Although not illustrated, in an example embodiment, a portion of the dimple pattern 121 may not vertically overlap the gate electrode GE.

In a plan view, at least a portion of the dimple pattern 121 may be disposed within the gate electrode GE. In an example embodiment, the entire dimple pattern 121 may be disposed within the gate electrode GE.

One or more dimple patterns 121 may be provided in an active region AR and/or under a gate electrode GE. In the present embodiment, two dimple patterns 121 are provided in an active region AR and under a gate electrode GE. When a plurality of dimple patterns 121 are provided, at least a portion of the dimple patterns 121 may vertically overlap the gate electrode GE, e.g., in a plan view. For example, all of the plurality of dimple patterns 121 may vertically overlap the gate electrode GE. Alternatively, a portion of the plurality of dimple patterns 121 may entirely overlap the gate electrode GE in a vertical direction, wherein a portion of the dimple patterns 121 may partially overlap the gate electrode GE in the vertical direction, while another portion of the dimple patterns 121 may not overlap the gate electrode GE in the vertical direction. For example, some of the plurality of dimple patterns 121 may entirely overlap the gate electrode GE in the vertical direction, some others of the dimple patterns 121 may partially overlap the gate electrode GE in the vertical direction, and the others of the dimple patterns 121 may not overlap the gate electrode GE in the vertical direction.

The dimple patterns 121 may be provided within a second trench TCH2 recessed from the upper surface 110s of the substrate 110. The upper surface 121s of the dimple patterns 121 may have a concave shape.

In an example embodiment, a depth d2 of the second trench TCH2 may be smaller than or equal to a depth d1 of the first trench TCH1. In an example embodiment, the depth d2 of the second trench TCH2 may be at least about 80% of the depth d1 of the first trench TCH1, for example, at least about 90% or at least about 95%. In an example embodiment, the depth d2 of the second trench TCH2 may be equal to the depth d1 of the first trench TCH1. Then, the active region AR may be defined by the device isolation pattern 120 and the dimple pattern 121. For example, a bottom boundary of the active region AR may be at the same level as a bottom surface of the isolation pattern 120.

The dimple pattern 121 may include the same material as the device isolation pattern 120, such as a silicon oxide, a silicon nitride, a silicon oxynitride, or a combination thereof, and may include a single layer or a plurality of layers.

The gate electrode GE may be disposed over the substrate 110 across the active region AR. For example, when the active region AR extends, e.g., lengthwise, in the second direction DR2, the gate electrode may extend, e.g., lengthwise, in the first direction DR1. The gate electrode GE may cover at least a portion of the dimple patterns 121. In an example embodiment, the gate electrode GE may completely cover the dimple patterns 121, and the dimple patterns 121 may be disposed inside the gate electrode GE in a plan view.

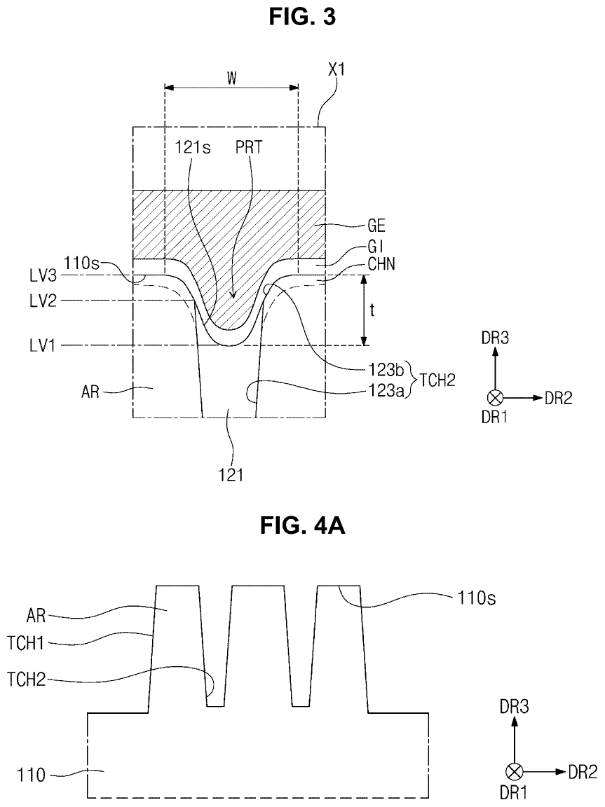

The gate electrode GE may have a protrusion PRT corresponding to and/or protruding toward a concave portion of the upper surface 121s of each of the dimple patterns 121. This will be described later with reference to FIG. 3.

The gate electrode GE may be formed of a conductive material. In an example embodiment, the gate electrode GE may include a conductive pattern and a barrier pattern, not illustrated, surrounding the conductive pattern. For example, the conductive pattern may be formed of one of the materials having a lower resistivity than the barrier pattern. For example, the conductive pattern may be formed of one of tungsten, copper, hafnium, zirconium, titanium, tantalum, aluminum, ruthenium, palladium, platinum, cobalt, nickel, conductive metal nitrides, or a combination thereof. The barrier pattern may cover a side surface and a bottom surface of the conductive pattern. The barrier pattern may be formed of a conductive material having a predetermined work function, e.g., a higher work function than the conductive pattern. For example, the barrier pattern may include metal layer/metal nitride layer. The metal layer may include at least one of titanium, tantalum, tungsten, nickel, cobalt, or platinum. The metal nitride layer may include at least one of titanium nitride (TiN), tantalum nitride (TaN), tungsten nitride (WN), nickel nitride (NiN), cobalt nitride (CoN), or platinum nitride (PtN).

A gate insulating pattern GI may be interposed between the gate electrode GE and the substrate 110.

The gate insulating pattern GI may cover the substrate 110 and the upper surface 121s of the dimple pattern 121 below the gate electrode GE. The gate insulating pattern GI may have a downwardly concave shape corresponding to the dimple pattern 121.

The gate insulating pattern GI may include a high-κ dielectric material having a higher dielectric constant than a silicon oxide. For example, the gate insulating pattern GI may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but the inventive concept is not limited thereto. Alternatively, the gate insulating pattern GI may be formed of a thermal oxide formed by thermally oxidizing the upper surface of the substrate 110.

Gate spacers SP may be disposed on the source/drain regions SD to cover opposite sidewalls of the gate electrodes 151. The gate spacer SP may be formed of an insulating material such as a silicon oxide or a silicon nitride.

Source/drain regions SD may be disposed on opposite sides of the gate electrode GE. The source/drain regions SD may include a first source/drain region SD1 provided on one side of the gate electrode GE and a second source/drain region SD2 provided on the other side of the gate electrode GE. The first source/drain region SD1 and the second source/drain region SD2 may be provided within the active region AR.

The first and second source/drain regions SD1 and SD2 may constitute a transistor together with the gate electrode GE, and may be a source region and a drain region of a transistor, respectively. For example, the first source/drain region SD1 may correspond to the drain region, and the second source/drain region SD2 may correspond to the source region.

The first and second source/drain regions SD1 and SD2 may be disposed on opposite sides of the gate electrode GE and may be disposed below the gate spacer SP. The first and second source/drain regions SD1 and SD2 may be formed by ion implantation of impurities into the active region AR using the gate electrode GE as an ion implantation mask. The first and second source/drain regions SD1 and SD2 may include impurities having a conductivity type opposite to that of the substrate 110.

The first source/drain region SD1 and the second source/drain region SD2 may be formed by substantially the same doping or ion implantation of impurities. For example, the first and second source/drain regions SD1 and SD2 may include the same impurities, e.g., per unit volume. The first and second source/drain regions SD1 and SD2 may be labeled interchangeably depending on the final transistor circuit configuration. For example, the active region AR may include P-type impurities, and the first and second source/drain regions SD1 and SD2 may include N-type impurities.

In an example embodiment, a dimple pattern 121 may be provided below the gate electrode GE.

FIG. 3 is an enlarged cross-sectional view of portion X1 of FIG. 2B, illustrating a portion in which the dimple pattern 121 is formed.

Referring to FIGS. 1 to 3, one or more second trenches TCH2 may be provided within the substrate 110, and a dimple pattern 121 may be provided within each second trench TCH2.

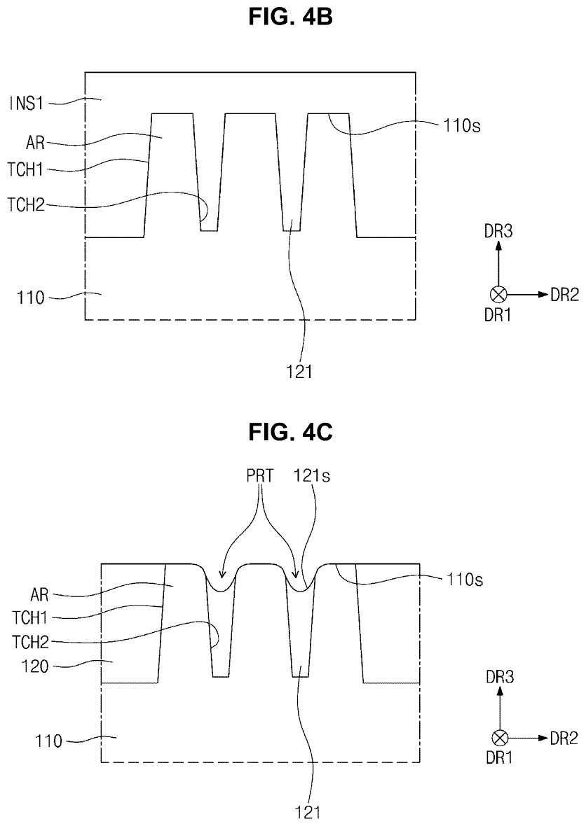

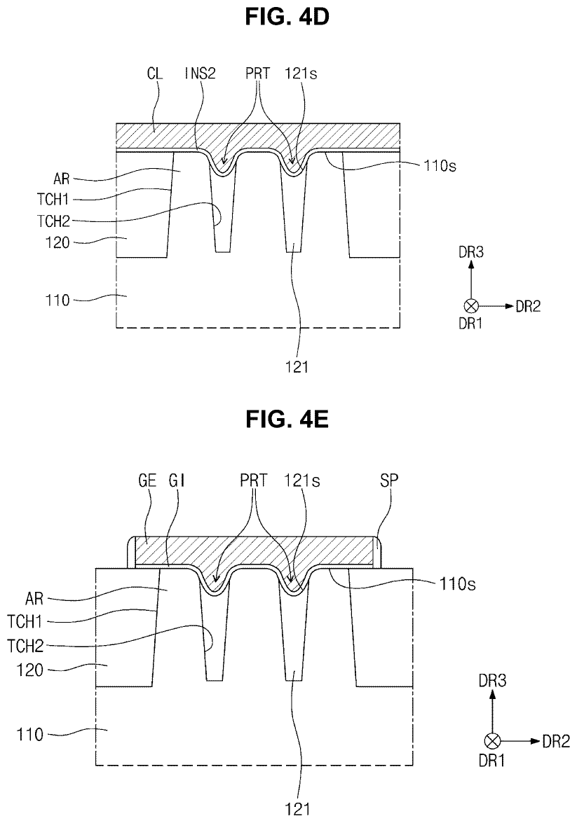

A second trench TCH2 may include a bottom surface and side surfaces. The side surfaces of the second trench TCH2 may include a first side surface 123a and a second side surface 123b having different angles with respect to the upper surface 110s of the substrate 110. The first side surface 123a may be connected to the bottom surface, and the second side surface 123b may be disposed above the first side surface 123a and correspond to or may be a side surface contacting the upper surface 110s of the substrate 110. The second side surface 123b may be an inclined surface with a smaller inclination angle than the first side surface 123a. For example, the first side surface 123a may have an inclination angle of about 70 degrees to about 90 degrees with respect to the upper surface 110s of the substrate 110. The second side surface 123b may have an inclination angle of about 45 degrees to about 80 degrees with respect to the upper surface 110s of the substrate 110. For example, the inclination angles of the side surfaces of the second trench may be acute angles between a line parallel to a sidewall of the second trench and a line parallel to the upper surface 110s of the substrate in a cross-sectional view. Each of the first side surface 123a and the second side surface 123b may be a substantially flat surface, or may be provided as a curved surface. When each of the first side surface 123a and the second side surface 123b is provided as a curved surface, the inclination angle may be a mean inclination angle of tangents lines of the first side surface 123a and of the second side surface 123b, respectively. The first side surface 123a may be a portion of the side surface of the second trench TCH2 formed by the trench forming process described below with respect to FIG. 4A, and the second side surface 123b may be a portion of the side surface of the second trench TCH2 formed by a process forming the dimple pattern 121 in the second trench TCH2 as described below with respect to FIG. 4C. For example, the first side surface 123a of the second trench TCH2 may be a portion of the side surface of the second trench TCH2 that contacts the dimple pattern 121, and the second side surface 123b of the second trench TCH2 may be a portion of the side surface of the second trench TCH2 that contacts the gate insulating pattern GI.

The dimple pattern 121 may fill at least a portion of the second trench TCH2. In an example embodiment, the dimple pattern 121 may fill the interior of the second trench TCH2 from the bottom surface of the second trench TCH2 to a point at which the first side surface 123a and the second side surface 123b are in contact with each other. For example, the dimple pattern 121 may have a concave upper surface 121s. In an example embodiment, an edge of the upper surface 121s of the dimple pattern 121 may abut on or contact an edge of the second side surface 123b.

When viewed in a cross-section, if a height of a lowest point of the upper surface 121s of the dimple pattern 121 is defined as a first level LV1 and a height of a highest point of the upper surface 121s of the dimple pattern 121 is defined as a second level LV2, then the first level LV1 may be lower than the second level LV2. For example, from the upper surface 110s of the substrate 110, a central portion of the dimple pattern 121 may be farther away than the edge of the dimple pattern 121, e.g., in a vertical direction.

In an example embodiment, an upper surface of the device isolation pattern 120, vertically overlapping the gate electrode GE, may be a flat surface or a substantially flat surface. The upper surface of the device isolation pattern 120 may be at the same level or substantially at the same level as (for example, substantially coplanar with) the upper surface 110s of the substrate 110. For example, if a height of the upper surface of the device isolation pattern 120, vertically overlapping the gate electrode GE, is defined as a third level LV3, then the third level LV3 may be the same or substantially the same as the height of the upper surface 110s of the substrate 110. Accordingly, the third level LV3 may be higher than the second level LV2 and the first level LV1. For example, the highest point of the upper surface 121s of the dimple pattern 121 may be at a lower level than the upper surface of the device isolation pattern 120 and the upper surface 110s of the substrate 110.

In an example embodiment, when a portion of the upper surface of the device isolation pattern 120 is a concave curved surface, a lowest point of the upper surface of the device isolation pattern 120 may be at a lower level than the upper surface 110s of the substrate 110. Even in this case, the upper surface of the device isolation pattern 120 may be disposed closer in the vertical direction to the upper surface 110s of the substrate 110 than the upper surface 121s of the dimple pattern 121.

The gate electrode GE may be provided on the dimple pattern 121 with the gate insulating pattern GI interposed therebetween. The gate electrode GE may have a lower surface corresponding to the shapes of the upper surface 121s of the dimple pattern 121 and the second side surface 123b of the second trench TCH2. For example, the gate electrode GE may have a protrusion PRT corresponding to the upper surface 121s of the dimple pattern 121 and the second side surface 123b of the second trench TCH2. For example, the protrusion PRT of the gate electrode GE may protrude toward the upper surface 121s of the dimple pattern 121. Accordingly, in the gate electrode GE, the lower surface of the portion vertically overlapping the dimple pattern 121 may be at a lower level than the lower surface of the portion vertically overlapping the device isolation pattern 120.

A channel region CHN may be formed in the active region AR below the gate electrode GE due to the operation of the transistor, for example, as a voltage is applied to the gate electrode GE. The channel region CHN may be formed below the gate electrode GE, for example, in an inclined region adjacent to the upper surface 110s of the substrate 110 and the second side surface 123b of the second trench TCH2. The protrusion PRT of the gate electrode GE may also surround the channel region CHN below the gate electrode GE from a side surface of the gate electrode GE. For example, the channel region CHN may be formed along side surfaces of the protrusion PRT of the gate electrode GE thereby expanding the area of the channel region CHN. Accordingly, the channel region CHN may be provided in a fin-like channel shape between the source/drain regions, and the transistor may operate similarly to a fin-type transistor. For example, the fin-like channel and the fin-type transistor may be respectively the channel and the transistor formed with the above described dimple pattern.

A distance t in a vertical direction from the upper surface 110s of the substrate 110 to the lowest point of the upper surface 121s of the dimple pattern 121 may be proportional to a size of the channel region CHN. The larger the distance t from the upper surface 110s of the substrate 110 to the lowest point of the upper surface 121s of the dimple pattern 121, the larger the size of the channel region CHN. In an example embodiment, a width (e.g., a horizontal width) w of an uppermost portion of the second trench TCH2 may be smaller than or equal to twice the distance (e.g., a vertical distance) t from the upper surface 110s of the substrate 110 to the lowest point of the upper surface 121s of the dimple pattern 121 (w≤2t).

In an example embodiment, the dimple pattern 121 may be provided in a rectangular shape in a plan view, but the inventive concept is not limited thereto. For example, the dimple pattern 121 may be provided in a circular, elliptical, or polygonal shape in a plan view. Also, the dimple pattern 121 may be elongated in one direction, e.g., in the plan view.

In an example embodiment, a length or width of the channel region CHN formed between the source/drain regions SD may be controlled by variously changing the shape and number of the dimple patterns 121. For example, an effective channel length may be increased by variously changing the shape or number of the dimple patterns 121. As a result, a higher current density may be achieved while reducing the switching time of the transistor.

FIGS. 4A to 4E are cross-sectional views corresponding to FIG. 2B, sequentially illustrating a method of manufacturing a semiconductor device according to an example embodiment.

Referring to FIG. 4A, mask patterns, not illustrated, may be formed on the substrate 110, and a patterning/etching process may be performed using the mask patterns as an etching mask to form first trenches TCH1, second trenches TCH2, and active regions AR. The second trenches TCH2 may be formed in a region to overlap a gate electrode GE in consideration of a location at which the gate electrode GE is to be formed. Each of the second trenches TCH2 may have a first side surface 123a (see FIG. 3).

In an example embodiment, the first trenches TCH1 and the second trenches TCH2 may be formed using the same patterning process. Accordingly, depths of the first trenches TCH1 and the second trenches TCH2 may be the same. In an example embodiment, the second trenches TCH2 may be formed with a narrower width than the first trenches TCH1. For example, when the width of the trenches is formed below a certain range, etching rate may be lower. Accordingly, the degree of etching of the second trenches TCH2 may be less than the degree of etching of the first trenches TCH1. For example, the depth of the second trenches TCH2 may be smaller than the depth of the first trenches TCH1. A difference in depth between the first trenches TCH1 and the second trenches TCH2 may fall within a process margin range.

Referring to FIG. 4B, a first insulating layer INS1 may be formed to fill the first and second trenches TCH1 and TCH2.

The first insulating layer INS1 may be formed of insulating materials forming the device isolation pattern 120 (see FIG. 3) and the dimple pattern 121 (see FIG. 3). For example, the first insulating layer INS1 may include a silicon oxide, a silicon nitride, a silicon oxynitride, fluorine-doped silicate glass (FSG), a low-κ dielectric, or a combination thereof.

When the first insulating layer INS1 fills the first and second trenches TCH1 and TCH2, insulating materials may be deposited to different degrees depending on the widths of the first and second trenches TCH1 and TCH2. For example, a region in which the first trench TCH1 is formed has a relatively large width and a region in which the second trench TCH2 is formed has a relatively small width, so that the insulating materials may be deposited more easily in the first trench TCH1 than in the second trench TCH2. As a result, the first trench TCH1 may be completely filled or overfilled, and the second trench TCH2 may be underfilled.

Referring to FIG. 4C, the first insulating layer INS1 may be planarized until the upper surface 110s of the substrate 110, for example, an upper surfaces of the active patterns AR, are exposed. The planarization of the first insulating layer INS1 may be performed using an etch-back process or a chemical mechanical polishing (CMP) process. The planarized substrate 110 may be cleaned.

A portion of the first insulating layer INS1 may be removed to form the device isolation pattern 120 in the first trench TCH1 and form the dimple pattern 121 in the second trench TCH2.

During the planarization process of the upper surface 110s of the substrate 110 and the first insulating layer INS1, the substrate 110 and the first insulating layer INS1 may be etched to different degrees depending on the stacked degree, etching rate, and exposed area of each of the substrate 110 and the first insulating layer INS1. For example, the insulating materials forming the first insulating layer INS1 may have a higher etching rate than the material of the substrate 110. Also, the first trench TCH1 has a larger width than the second trench TCH2, so that the first insulating layer INS1 in the region in which the first trench TCH1 is formed may have a larger area exposed to the outside than the region in which the second trench TCH2 is formed. In addition, the first insulating layer INS1 may be deposited to different degrees in the first and second trenches TCH1 and TCH2. Accordingly, the first insulating layer INS1 in the second trench TCH2 may be etched more than the first insulating layer INS1 in the first trench TCH1.

As a result, the substrate 110, the device isolation pattern 120, and the dimple pattern 121 may be formed with different shapes and depths depending on their respective degrees of etching. For example, a dimple may be formed on the upper surface 121s of the dimple pattern 121 to have a concave shape. Accordingly, the upper surface 121s of the dimple pattern 121 may be at a lower level than the upper surface of the device isolation pattern 110.

After etching the first insulating layer INS1 and the upper surface 110s of the substrate 110, the upper surface of the device isolation pattern 120 and the upper surface 110s of the substrate 110 may be substantially flat or coplanar. However, the upper surface of the device isolation pattern 120 and the upper surface 110s of the substrate 110 may not be an entirely flat surface in certain examples. At least a portion of the upper surface of the device isolation pattern 120 and the upper surface 110s of the substrate 110 adjacent to the device isolation pattern 120 and the dimple pattern 121 may be a curved surface. In the drawings, the device isolation pattern 120 is illustrated as a flat surface, but at least a portion of the upper surface of the device isolation pattern 120 may also be a curved surface in certain embodiments.

During the etching of the portion of the first insulating layer INS1 corresponding to the dimple pattern 121, the adjacent upper surface 110s of the substrate 110 may also be additionally etched to form an inclined surface. For example, when a portion of the first insulating layer INS1 in the second trench TCH2 is etched and removed, an edge region in which the side surface of the second trench TCH2 and the upper surface 110s of the substrate 110 meet may be exposed to the outside. The exposed edge region may be susceptible to etching and may be additionally etched, similarly to chamfering observed during an etch-back process and/or a planarization process. An inclined surface of the additionally etched substrate 110 may constitute the second side surface 123b (see FIG. 3) of the second trench TCH2.

Referring to FIG. 4D, a second insulating layer INS2 and a conductive layer CL may be sequentially formed on the substrate 110.

The second insulating layer INS2 may be conformally formed on the substrate 110 and may be formed of a material forming the gate insulating pattern GI. For example, the second insulating layer INS2 may be formed of a high-κ dielectric material having a higher dielectric constant than a silicon oxide. For example, the gate insulating pattern GI may be formed of at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but the inventive concept is not limited thereto.

A conductive layer CL may be formed on the second insulating layer INS2. The conductive layer CL may be formed of a material forming the gate electrode GE. For example, the conductive layer CL may be formed of various conductive materials, for example, one of tungsten, copper, hafnium, zirconium, titanium, tantalum, aluminum, ruthenium, palladium, platinum, cobalt, nickel, conductive metal nitrides, or a combination thereof. Although not illustrated, the conductive layer CL may include a plurality of layers, and the conductive layer CL may include a first conductive layer, not illustrated, for a barrier pattern and a second conductive layer, not illustrated, for a conductive pattern. The first conductive layer and the second conductive layer may be formed of materials forming the barrier pattern and the conductive pattern, respectively.

Referring to FIG. 4E, the conductive layer CL and the second insulating layer INS2 may be patterned to form a gate electrode GE and a gate insulating pattern GI. Gate spacers SP may be additionally formed on opposite sides of the gate electrode GE and the gate insulating pattern GI.

The patterning of the conductive layer CL and the second insulating layer INS2 may be achieved by forming mask patterns on the conductive layer CL and performing a patterning/etching process using the mask patterns as an etching mask.

As described above, according to an example embodiment, a dimple pattern 121 may be formed simultaneously in the same process of forming a device isolation pattern 120.

For example, when a semiconductor device is manufactured, the dimple pattern 121 may be formed without an additional mask to facilitate the implementation of a fin-like channel within a transistor.

The semiconductor device according to an example embodiment may be employed in various integrated circuit devices. For example, the semiconductor device may be employed in a memory device based on semiconductor devices. The memory device may be a volatile memory such as a dynamic random-access memory (DRAM), a synchronous dynamic random-access memory (SDRAM), a double data rate synchronous dynamic random-access memory (DDR SDRAM), a low power double data rate synchronous dynamic random-access memory (LPDDR SDRAM), a graphics double data rate synchronous dynamic random-access memory (GDDR SDRAM), a double data rate type two synchronous dynamic random-access memory (DDR2 SDRAM), a double data rate type three synchronous dynamic random-access memory (DDR3 SDRAM), a double data rate fourth-generation synchronous dynamic random-access memory (DDR4 SDRAM), a thyristor random-access memory (TRAM), or the like, or a non-volatile memory such as a phase-change random-access memory (PRAM), a magnetic random-access memory (MRAM), a resistive random-access memory (RRAM), or the like.

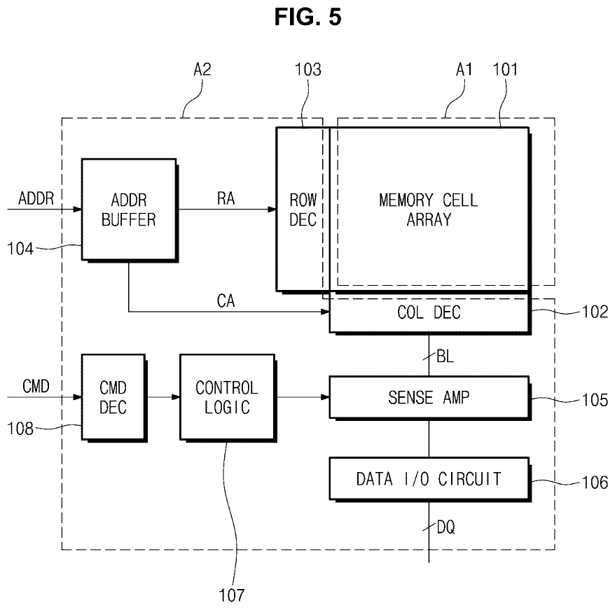

FIG. 5 is a block diagram of an integrated circuit device according to an example embodiment.

Referring to FIG. 5, the integrated circuit device includes a memory cell region A1 and a peripheral circuit region A2.

The memory cell region A1 may include a memory cell array 101. The peripheral circuit region A2 may include a command decoder 108, a control logic 107, an address buffer 104, a row decoder 103, a column decoder 102, a sense amplifier 105, and a data input/output circuit 106. The peripheral circuit region A2 may output data through data lines DQ in response to commands CMD, addresses ADDR, and control signals received from an external device such as a memory controller.

The memory cell array 101 includes a plurality of memory cells, not illustrated, arranged two-dimensionally or three-dimensionally. For example, the memory cell array 101 may include a plurality of memory cells arranged in a matrix of a plurality of rows and a plurality of columns. The memory cells may be electrically connected between wordlines, not illustrated, and bitlines BL that cross each other.

Each of the memory cell may include a data storage element and a selection element, and the selection element and the data storage element may be electrically connected in series.

The data storage element may be electrically connected between the bitline BL and the selection element, and the selection element may be electrically connected between the data storage element and the wordline.

The selection element may be a field-effect transistor (FET). For example, the data storage element may be a capacitor including a lower electrode, a dielectric layer, and an upper electrode. In this case, the semiconductor memory device according to an example embodiment may be a dynamic random access memory (DRAM). For example, the data storage element may include a magnetic tunnel junction pattern. In this case, the semiconductor memory device according to an example embodiment may be a magnetic random access memory (MRAM). For example, the data storage element may include a phase change material or a variable resistance material. In this case, the semiconductor memory device according to an example embodiment may be a phase-change random access memory (PRAM) or a resistive random access memory (ReRAM). However, these are only examples, and the inventive concept is not limited thereto. The data storage element may include various structures and/or materials capable of storing data.

The command decoder 108 may decode a write enable signal, a row address strobe signal, a column address strobe signal, a chip select signal, or the like, received from an external device such as a memory controller, to generate control signals corresponding to the command CMD in the control logic 107. The command CMD may include an active command, a read command, a write command, a precharge command, or the like.

The address buffer 104 may receive the address ADDR from the memory controller, the external device. The address ADDR may include a row address RA that addresses rows of the memory cell array 101, and a column address CA that addresses columns of the memory cell array. The address buffer 104 may transmit the row address RA to the row decoder 103 and the column address CA to the column decoder 102.

The row decoder 103 may select one of the plurality of wordlines electrically connected to the memory cell array 101. The row decoder 103 may decode the row address RA received from the address buffer 104, select a single wordline corresponding to the row address RA, and activate the selected wordline.

The column decoder 102 may select one of the plurality of bitlines BL of the memory cell array 101. The column decoder 102 may decode the column address CA, received from the address buffer 104, to select a predetermined bitline BL corresponding to the column address CA.

The sense amplifier 105 may be electrically connected to the bitlines BL of the memory cell array 101. The sense amplifier 105 may sense a voltage or a voltage change in the selected bitline BL, among the plurality of bitlines BL, amplify the sensed voltage, and output the amplified voltage. The data input/output circuit 106 may output data, output based on the sensed and amplified voltage, from the sense amplifier 105 to the outside through data lines DQ.

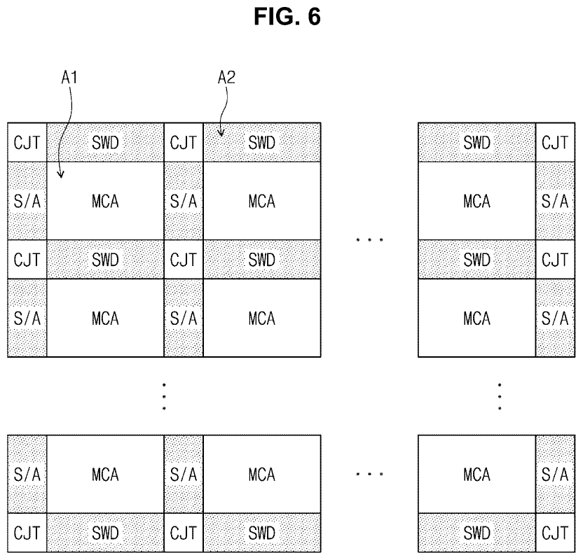

FIG. 6 is a layout diagram of a semiconductor device according to an example embodiment.

Referring to FIG. 6, an integrated circuit device may include a plurality of memory cell regions A1. Each of the plurality of memory cell regions A1 may be surrounded by a peripheral circuit region A2. The peripheral circuit region A2 may refer to all regions surrounding the memory cell region A1, other than the memory cell region A1.

In some embodiments, each of the plurality of memory cell regions A1 may be a memory cell region MCA of a DRAM device, and the peripheral circuit region A2 may be a region in which peripheral circuits of the DRAM device are formed and a core region/area (hereinafter referred to as a “peripheral circuit region A2”).

In the peripheral circuit region A2, circuits for reading data from the memory cell region A1 or writing data in the memory cell region A1, circuits for signal processing, and circuits for power supply may be disposed. The peripheral circuit region A2 may include a sub-wordline driver block SWD, a sense amplifier block S/A, and a conjunction block CJT. A plurality of sense amplifiers (see FIG. 5) may be disposed in the sense amplifier block S/A. The conjunction block CJT may be disposed at an intersection of the sub-wordline driver block SWD and the sense amplifier block S/A. In the conjunction block CJT, power drivers and ground drivers for driving the sense amplifiers may be alternately disposed. In the peripheral circuit region A2, peripheral circuits such as an inverter chain and an input/output circuit may be further formed.

In the integrated circuit device according to an example embodiment, a plurality of transistors may be disposed in the peripheral circuit region A2. For example, transistors of sense amplifiers may be disposed in the sense amplifier block S/A.

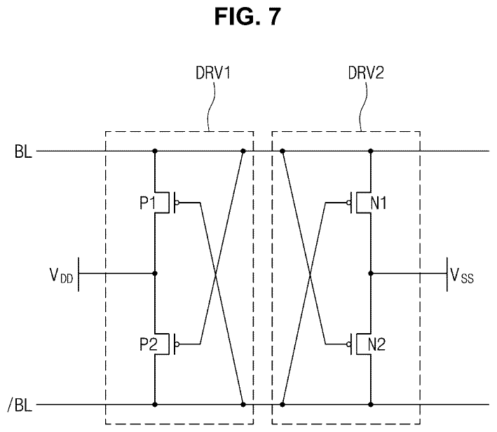

FIG. 7 is an equivalent circuit diagram of a sense amplifier according to an example embodiment.

Referring to FIG. 7, the sense amplifier may include a first driver DRV1 and a second driver DRV2 electrically connected between a pair of bitlines BL and /BL. The pair of bitlines include a first bitline BL and a second bitline /BL, and the second bitline /BL may be a complementary bitline.

The first driver DRV1 may include first and second PMOS transistors P1 and P2 electrically connected in series between the pair of bitlines BL and /BL, and the second driver DRV2 may include first and second NMOS transistors N1 and N2 electrically connected in series between the pair of bitlines.

When a voltage level of the first bitline BL is higher than a voltage level of the second bitline /BL, the first PMOS transistor P1 and the second NMOS transistor N2 may be turned on, and the second PMOS transistor P2 and the first NMOS transistor N1 may be turned off in the meantime. The voltage of the first bitline BL may be amplified to the level of a first power supply voltage VDD, and the voltage of the second bitline /BL may be amplified to the level of a second power supply voltage VSS.

Conversely, when the voltage level of the second bitline /BL is higher than the voltage level of the first bitline BL, the first PMOS transistor P1 and the second NMOS transistor N2 may be turned off, and the second PMOS transistor P2 and the first NMOS transistor N1 may be turned on in the meantime. The voltage of the second bitline /BL may be amplified to the level of the first power supply voltage VDD, and the voltage of the first bitline BL may be amplified to the level of the second power supply voltage VSS.

In an example embodiment, the semiconductor device described with reference to FIGS. 1 to 3 may be applied to a pair of NMOS transistors and/or PMOS transistors constituting a sense amplifier.

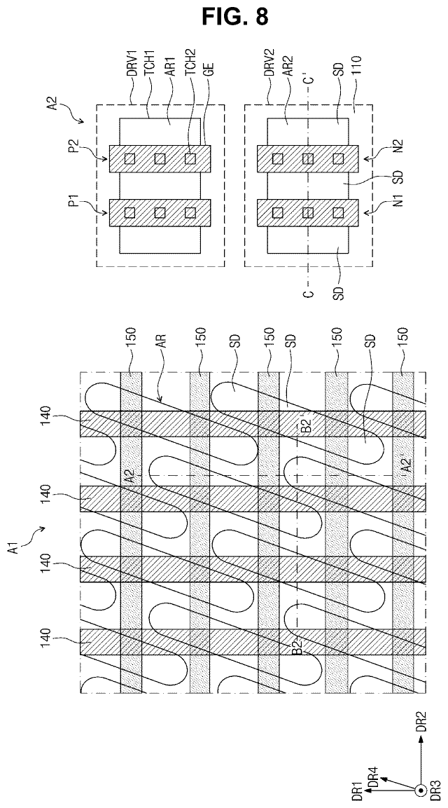

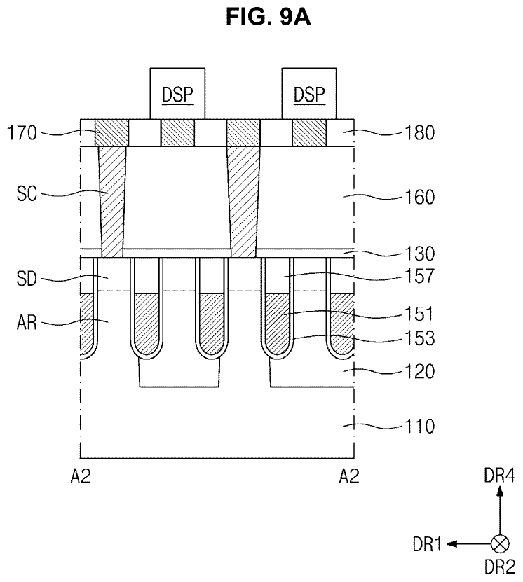

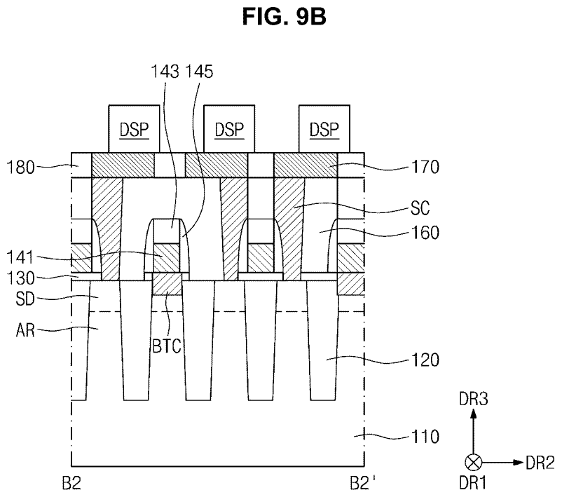

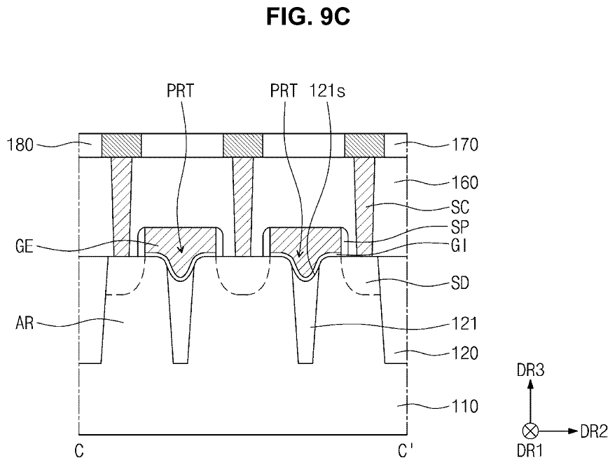

FIG. 8 is a plan view of an integrated circuit device including a semiconductor device according to an example embodiment. FIGS. 9A to 9C are cross-sectional views of an integrated circuit device according to an example embodiment, taken along lines A2-A2′, B2-B2′, and C-C′ of FIG. 8, respectively.

Referring to FIG. 8 and FIGS. 9A to 9C, the substrate 110 may include a memory cell region A1 and a peripheral circuit region A2. For ease of description, the memory cell region A1 will be described first, followed by the peripheral circuit region A2.

In the memory cell region A1, the integrated circuit device may include a substrate 110, source/drain regions SD, a wordline structure 150, a bitline structure 140, a bitline contact BTC, a storage node contact SC, a landing pad 170, and a data storage pattern DSP.

The substrate 110 may include, for example, a group IV semiconductor, a group III-V compound semiconductor, or a group II-VI compound semiconductor. For example, the group IV semiconductor may include silicon, germanium, or silicon-germanium. The substrate 110 may be a silicon substrate, a silicon-on-insulator (SOI) substrate, a germanium substrate, a germanium-on-insulator (GOI) substrate, a silicon-germanium substrate, or a substrate including an epitaxial layer.

The substrate 110 may include active regions AR and a device isolation pattern 120.

The device isolation pattern 120 may be disposed within the substrate 110 and define the active regions AR. The active regions AR may be spaced apart from each other in a first direction DR1 and a second direction DR2, which intersect each other (for example, orthogonally). The first direction DR1 and the second direction DR2 may be parallel to a lower surface of the substrate 110.

The device isolation pattern 120 may separate the active regions AR from each other while surrounding the active regions AR. The device isolation pattern 120 may include a silicon oxide, a silicon nitride, a silicon oxynitride, fluorine-doped silicate glass (FSG), a low-κ dielectric, or a combination thereof. The device isolation pattern 120 may include a single layer or a plurality of layers. In an example embodiment, the device isolation pattern 120 may include a silicon oxide layer.

Each of the active regions AR may have an isolated island shape and may be in the form of a bar elongated in the fourth direction DR4. The fourth direction DR4 may be parallel to the lower surface of the substrate 110 and intersect the first and second directions DR1 and DR2. The fourth direction DR4 may intersect the first direction DR1 at an angle other than 90 degrees, for example, an acute angle. In a plan view, the active regions AR may be portions of the substrate 110 surrounded by the device isolation pattern 120. The active regions AR may protrude from the other part of the substrate 110 in a third direction DR3, perpendicular to the lower surface of the substrate 110. For example, the active region AR may extend upward in the third direction DR3, e.g., between the device isolation pattern 120. The device isolation pattern 120 may include an insulating material, and may include at least one of, for example, a silicon oxide, a silicon nitride, or a combination thereof.

The source/drain regions SD may be provided within the substrate 110, for example, within the active regions AR. Each of the source/drain regions SD may be provided as a source region or a drain region of a transistor. For example, with respect to a single active region AR, two wordline structures 150 may cross over the single active region AR. A drain region may be formed between two wordline structures 150, while source regions may be formed on the opposite sides of the drain region relative to the two wordline structures 150. The source region and the drain region are formed by doping or ion implantation of the same or substantially the same impurities, and may be referred to interchangeably depending on the circuit configuration of the finally formed transistor. The source/drain regions SD may include impurities having a conductivity type opposite to that of the substrate 110. For example, the active regions AR may include P-type impurities, while the source/drain regions SD may include N-type impurities.

A plurality of wordline structures 150 may be provided in the memory cell region A1. The wordline structures 150 may extend lengthwise in the second direction DR2 and be spaced apart from each other in the first direction DR1. The wordline structures 150 may cross the active region AR.

The wordline structures 150 and the source/drain regions SD may constitute a buried channel array transistor (BCAT).

The wordline structures 150 may be buried within the substrate 110. Each of the wordline structures 150 may include a gate electrode 151, a gate insulating pattern 153, and a gate capping pattern 157.

The gate electrode 151 may cross the active regions AR and the device isolation pattern 120 in the second direction DR2. The gate insulating pattern 153 may be interposed between the gate electrode 151 and the active regions AR and between the gate electrode 151 and the device isolation pattern 120. The gate capping pattern 157 may cover the gate electrode 151 on the gate electrode 151.

A buffer pattern 130 may be disposed on the substrate 110. The buffer pattern 130 may cover the active regions AR, the device isolation pattern 120, and the wordline structures 150. In an example embodiment, the buffer pattern 130 may include at least one of a silicon oxide, a silicon nitride, a silicon oxynitride, or a combination thereof.

The bitline structures 140 may extend lengthwise in the first direction DR1 and may be spaced apart from each other in the second direction DR2. The bitline structures 140 may have a bar shape extending in the first direction DR1. Each of the bitline structures 140 may include a bitline 141 and a bitline capping pattern 143 on the bitline 141.

The bitline contact BTC may be provided on each of the active regions AR, and a plurality of bitline contacts BTC may be provided on the active regions AR. The bitline contacts BTC may be electrically connected to and/or contact a portion of the source/drain regions SD within the active regions AR, respectively. The bitline contacts BTC may be spaced apart from each other in the first and second directions DR1 and DR2. The bitline contacts BTC may be interposed between the active regions AR and the bitlines 141, respectively. Each of the bitline contacts BTC may electrically connect a corresponding bitline 141, among the bitlines 141, and a corresponding source/drain region SD.

A bitline capping pattern 143 may be provided on an upper surface of the bitline 141. A plurality of bitline capping patterns 143 may be provided on upper surfaces of the bitlines 141, respectively. The bitline capping patterns 143 may each extend lengthwise in the first direction DR1 along a corresponding bitline 141, and may be spaced apart from each other in the second direction DR2. The bitline capping patterns 143 may vertically overlap the bitlines 141.

A bitline spacer 145 may be provided on a side surface of the bitline 141 and a side surface of the bitline capping pattern 143. A plurality of bitline spacers 145 may be provided on side surfaces of the bitlines and side surfaces of the bit line capping patterns 143. The bitline spacers 145 may cover the side surfaces of the bitlines 141 and the side surfaces of the bitline capping patterns 143.

The storage node contact SC may be provided between adjacent bitlines 141. A plurality of storage node contacts SC may be provided in the memory cell region A1, and the storage node contacts SC may be spaced apart from each other in the first and second directions DR1 and DR2.

The storage node contact SC may extend inwardly of the substrate 110 to be in contact with a portion of the source/drain region SD of the active region AR, and may be electrically connected to a corresponding source/drain region SD. The storage node contacts SC may be formed of a conductive material, and may include, for example, at least one of polysilicon (Si), titanium (Ti), titanium nitride (TiN), tantalum (Ta), tantalum nitride (TaN), tungsten (W), tungsten nitride (WN), or aluminum (Al). In an example embodiment, the storage node contacts SC may include doped polysilicon, and may include N-type impurities such as phosphorus (P), arsenic (As), or antimony (Sb).

The storage node contacts SC may be spaced apart from each other in the first direction DR1 by fence patterns 160 on the wordline structures 150.

The fence patterns 160 may be disposed between the bitline structures 140, and may vertically overlap the wordline structures 150. The fence patterns 160 may be alternately disposed with the storage node contacts SC in the first direction DR1. The fence patterns 160 may spatially separate the storage node contacts SC from each other, and may electrically insulate the storage node contacts SC from each other. Lower surfaces of the fence patterns 160 may be in contact with the gate capping patterns 157 of the wordline structures 150.

The fence patterns 160 may include an insulating material, and may include, for example, a silicon nitride.

The landing pad 170 may be provided on a storage node contact SC. A plurality of landing pads 170 may be provided on the storage node contacts SC respectively, and the landing pads 170 may be spaced apart from each other in the first and second directions DR1 and DR2. The landing pads 170 may be electrically connected to and/or contact corresponding storage node contacts SC, respectively. The landing pad 170 may cover an upper surface of the bitline capping pattern 143.

At least a portion of each of the landing pads 170 may vertically overlap a corresponding storage node contact SC. The landing pad 170 may include a metal material (for example, tungsten, titanium, tantalum, or the like).

A filling pattern 180 may surround the landing pads 170. The filling pattern 180 may be interposed between adjacent landing pads 170. In a plan view, the filling pattern 180 may be in the form of a mesh having holes through which the landing pads 170 penetrate. For example, the filling pattern 180 may include at least one of a silicon nitride, a silicon oxide, a silicon oxynitride, or a combination thereof. For example, the filling pattern 180 may include an empty space (for example, an air gap) including an air layer.

The data storage pattern DSP may be provided on a landing pad 170. A plurality of data storage patterns DSP may be provided on the landing pads 170, and the data storage patterns DSP may be spaced apart from each other in the first and second directions DR1 and DR2. Each data storage pattern DSP may be electrically connected to a corresponding second source/drain region SD2 through a corresponding landing pad 170 and a corresponding storage node contact SC.

For example, the data storage pattern DSP may be a capacitor including a lower electrode, a dielectric layer, and an upper electrode. In this case, the semiconductor memory device according to an example embodiment may be a dynamic random access memory (DRAM). For example, the data storage pattern DSP may include a magnetic tunnel junction pattern. In this case, the semiconductor memory device according to an example embodiment may be a magnetic random access memory (MRAM). For example, the data storage patterns DSP may include a phase change material or a variable resistance material. In this case, the semiconductor memory device according to an example embodiment may be a phase-change random access memory (PRAM) or a resistive random access memory (ReRAM). However, these are only examples, and the inventive concept is not limited thereto. The data storage patterns DSP may include various structures and/or materials capable of storing data.

In the peripheral circuit region A2, peripheral circuits including row decoders and column decoders (see FIG. 5), a sense amplifier (see FIG. 5), and a controller, not illustrated, may be disposed on the substrate 110. According to an example embodiment, the peripheral circuits may include transistors, resistors, and capacitors, electrically connected to a memory cell array. In an example embodiment, the transistors in the memory cell region A1 may be provided in a buried form, and the transistors in the peripheral circuit region A2 may be provided in a flat/planar form.

In an example embodiment, at least a portion of the transistors in the peripheral circuit region A2 may be provided in a flat/planar form but provided as fin-like transistors described in FIGS. 1 to 3.

For example, the peripheral circuit region A2 may include a sense amplifier, and the transistors in the sense amplifier may be provided as fin-like transistors.

The sense amplifier may include first and second PMOS transistors P1 and P2, constituting a first driver DRV1, and first and second NMOS transistors N1 and N2 constituting a second driver DRV2.

The first and second PMOS transistors P1 and P2 may be provided in a first active region AR1, and the first and second NMOS transistors N1 and N2 may be provided in a second active region AR2. The first active region AR1 may be formed by ion implantation of N-type impurities, while the second active region AR2 may be formed by ion implantation of P-type impurities.

In the first driver DRV1, a gate electrode GE of the first PMOS transistor P1 and a gate electrode of the second PMOS transistor P2 may be provided on the substrate 110. Source/drain regions SD may be provided on opposite sides of the first PMOS transistor P1 and the second PMOS transistor P2, and between the first PMOS transistor P1 and the second PMOS transistor P2. In the second driver DRV2, a gate electrode GE of the first NMOS transistor N1 and a gate electrode of the second NMOS transistor N2 may be provided on the substrate 110. Source/drain regions SD may be provided on opposite sides of the first NMOS transistor N1 and the second NMOS transistor N2, and between the first NMOS transistor N1 and the second NMOS transistor N2. Each gate electrode GE and the source/drain regions SD provided on opposite sides of each gate electrode GE may constitute a corresponding transistor.

In each transistor of the first and second drivers DRV1 and DRV2, at least one second trench TCH2 may be provided in the substrate 110, and a dimple pattern 121 may be provided in the second trench TCH2. Each gate electrode GE may include a protrusion PRT corresponding to the dimple patterns 121.

In an example embodiment, a portion of the transistors in each of the first and second drivers DRV1 and DRV2 may be provided in the same layer as a portion of the components of the memory cell region A1. Also, in an example embodiment, a portion of the transistors in each of the first and second drivers DRV1 and DRV2 may be formed of the same material as a portion of the components of the memory cell region A1, and a portion of the transistors in each of the first and second drivers DRV1 and DRV2 may be manufactured using the same process as a portion of the components of the memory cell region A1. For example, the gate electrodes GE of the peripheral circuit region A2 may be provided in the same layer as the bitlines 141 of the memory cell region A1. Also, in each transistor of the first and second drivers DRV1 and DRV2, the gate electrodes GE may be manufactured using the same manufacturing process as a process of manufacturing the bitlines 141.

In an example embodiment, the shape and number of the dimple patterns 121 in at least a portion of the transistors of the first and second drivers DRV1 and DRV2 may be varied in different ways to control the channel length and width between the source/drain regions. For example, the shape or number of the dimple patterns 121 may be varied in different ways to increase the effective channel length. As a result, switching time of the transistors may be reduced and higher current density may be achieved.

In an integrated circuit device having the above-described structure, mismatch between transistors within the peripheral circuit region, for example, between transistors within the sense amplifier, may be reduced. This will be described as follows.

When the sense amplifier operates, a minute potential difference between a pair of bitlines BL and /BL should be accurately sensed and amplified. To this end, the first and second PMOS transistors P1 and P2 should have the same electrical characteristics (for example, threshold voltage), and the first and second NMOS transistors N1 and N2 should have the same electrical characteristics (for example, threshold voltage).

However, mismatch between transistors constituting the sense amplifier may occur due to random dopant fluctuation (RDF) during formation of the channel region CHN. For example, when impurities are implanted into the channel region CHN, the location and density of the impurities may randomly fluctuate to cause mismatch between transistors. RDF may be a major cause of threshold voltage variations in each transistor. Mismatch between transistors may be reduced as a channel area of the transistors increases. However, increasing an area of the gate electrodes 151 of the transistors in the sense amplifier may lead to an increase in the area occupied by the sense amplifier in the peripheral circuit region.

In an example embodiment, a dimple pattern may be formed below a gate electrode to effectively control channel size, for example, channel length and width. A gate electrode may include a protrusion corresponding to the dimple pattern. The gate electrode including the protrusions may be provided to surround or to expand the channel. Accordingly, the transistor may be driven in the same way as or similarly to a fin field-effect transistor (FinFET).

As described above, a transistor of the semiconductor device according to an example embodiment may be provided in a small area in a plan view while implement a substantially large effective channel area three-dimensionally. As a result, mismatch between the transistors in the sense amplifier may be reduced.

As set forth above, according to example embodiments, a semiconductor device including a transistor with an increased effective channel length while maintaining a compact overall size may be provided.

In addition, according to example embodiments, an integrated circuit device with improved electrical characteristics while maintaining a reduced feature size may be provided. For example, an integrated circuit device with reduced mismatch between transistors constituting a sense amplifier may be provided.

While various embodiments have been described above, those skilled in the art will appreciate that various modifications, additions and substitutions are possible, without departing from the present inventive concepts. For example, in an example embodiment, transistors used in a sense amplifier of a peripheral circuit region are described as an example, but the present inventive concepts are not limited thereto. The embodiments of the present disclosure may be applied to various transistors included in other integrated circuits. As other examples, different figures illustrate different exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Therefore, example embodiments are only for illustrative purposes rather than limiting the present inventive concepts. The invention should be defined by the accompanying claims.

What is claimed is:

1. A semiconductor device comprising:
a substrate having a first trench and a second trench;
a device isolation pattern in the first trench to define an active region in the substrate;
a gate insulating pattern on the active region;
a gate electrode on the gate insulating pattern; and
a dimple pattern filling at least a portion of the second trench and having a concave upper surface,
wherein:
at least a portion of the dimple pattern overlaps the gate electrode in a plan view; and
a depth of the second trench is in a range from 80% to 100% of a depth of the first trench.

2. The semiconductor device of claim 1, wherein:
the gate electrode has a protrusion protruding toward the concave upper surface of the dimple pattern.

3. The semiconductor device of claim 1, wherein:
the second trench comprises a bottom surface and a side surface;
the side surface comprises a first side surface, connected to the bottom surface, and a second side surface connected to the first side surface and an upper surface of the substrate; and
the first side surface and the second side surface have different inclination angles with respect to the upper surface of the substrate.

4. The semiconductor device of claim 3, wherein:
the second side surface has an inclination angle of 45 degrees to 80 degrees with respect to the upper surface of the substrate.

5. The semiconductor device of claim 1, wherein:
a horizontal width of an uppermost portion of the second trench is smaller than or equal to twice a vertical distance from an upper surface of the substrate to a lowest point of the concave upper surface of the dimple pattern.

6. The semiconductor device of claim 1, wherein:
the substrate includes a plurality of second trenches;
a plurality of dimple patterns are provided in the plurality of second trenches; and
at least a portion of each of the dimple patterns overlaps the gate electrode in the plan view.

7. A semiconductor device comprising:
a substrate having an active region defined by a device isolation pattern;
a dimple pattern defined by the active region;
a gate electrode on the active region, and comprising a portion vertically overlapping the dimple pattern and a portion vertically overlapping the device isolation pattern; and
a gate insulating pattern between the gate electrode and the active region,
wherein:
an upper surface of the dimple pattern is disposed farther from an upper surface of the substrate in a vertical direction than an upper surface of the device isolation pattern is to the upper surface of the substrate in the vertical direction in a portion vertically overlapping the gate electrode.

8. The semiconductor device of claim 7, wherein:
the upper surface of the device isolation pattern in the portion vertically overlapping the gate electrode is at the same level as the upper surface of the substrate.

9. The semiconductor device of claim 8, wherein:
the upper surface of the dimple pattern has a concave shape; and
a highest point of the upper surface of the dimple pattern, vertically overlapping the gate electrode, is at a lower level than the upper surface of the substrate.

10. The semiconductor device of claim 7, wherein:
a lower surface of a portion, vertically overlapping the dimple pattern, of the gate electrode is disposed at a lower level than a lower surface of a portion, vertically overlapping the device isolation pattern, of the gate electrode.

11. An integrated circuit device comprising:
a sense amplifier configured to detect a voltage of a bitline and comprising a first PMOS transistor, a second PMOS transistor, a first NMOS transistor, and a second NMOS transistor,
wherein:
at least one of the first PMOS transistor, the second PMOS transistor, the first NMOS transistor, and the second NMOS transistor comprises:
a substrate having a first trench and a second trench;
a device isolation pattern in the first trench to define an active region in the substrate;
a gate insulating pattern on the active region;
a gate electrode on the gate insulating pattern; and
at least one dimple pattern filling at least a portion of the second trench and having a concave upper surface;
at least a portion of the dimple pattern overlaps the gate electrode in a plan view; and
a depth of the second trench is in a range from 80% to 100% of a depth of the first trench.

12. The integrated circuit device of claim 11, comprising:
a memory cell region comprising a plurality of memory cells and a peripheral circuit region comprising the sense amplifier.

13. The integrated circuit device of claim 12, wherein:
at least a portion of the first PMOS transistor, the second PMOS transistor, the first NMOS transistor, and the second NMOS transistor is provided in the same layer as at least a portion of the memory cells.

14. The integrated circuit device of claim 13, wherein:
the memory cell region further comprises a wordline structure and a bitline structure, both electrically connected to the memory cells; and
gate electrodes of the first PMOS transistor, the second PMOS transistor, the first NMOS transistor, and the second NMOS transistor are provided in the same layer as at least a portion of the bitline structure.

15. The integrated circuit device of claim 11, further comprising a plurality of active regions defined by the device isolation pattern,
wherein:
the plurality of active regions include a first active region and a second active region having different conductivity-type impurities; and
the first and second PMOS transistors are provided in the first active region, and the first and second NMOS transistors are provided in the second active region.

16. The integrated circuit device of claim 11, wherein:
the gate electrode has a protrusion protruding toward the concave upper surface of the dimple pattern.

17. The integrated circuit device of claim 11, wherein:
the second trench comprises a bottom surface and a side surface;
the side surface comprises a first side surface, connected to the bottom surface, and a second side surface connected to the first side surface and an upper surface of the substrate; and
the first side surface and the second side surface have different inclination angles with respect to the upper surface of the substrate.

18. The integrated circuit device of claim 17, wherein:
the second side surface has an inclination angle of 45 degrees to 80 degrees with respect to the upper surface of the substrate.

19. The integrated circuit device of claim 11, wherein:
a horizontal width of an uppermost portion of the second trench is smaller than or equal to twice a vertical distance from an upper surface of the substrate to a lowest point of the concave upper surface of the dimple pattern.

20. The integrated circuit device of claim 11, wherein:
the at least one dimple pattern is a plurality of dimple patterns; and
at least a portion of each of the dimple patterns overlaps the gate electrode in the plan view.
